(19) United States
(12) Patent Application Publication
(10) Pub. No.: US 2013/0249628 A1
(43) Pub. Date: Sep. 26, 2013

(54) LOW NOISE CRYOGENIC AMPLIFIER

(71) Applicants: Stephen Rawson, Labastide D'anjou (FR); Bènoît Fauroux, Castelnaudary (FR); Rémii Rayet, Toulous (FR); Thomas Bonhoure, Avignonet Lauragais (FR); Cédric Chambon, Villefranche Lauragais (FR)

(72) Inventors: Stephen Rawson, Labastide D'anjou (FR); Bènoît Fauroux, Castelnaudary (FR); Rémii Rayet, Toulous (FR); Thomas Bonhoure, Avignonet Lauragais (FR); Cédric Chambon, Villefranche Lauragais (FR)

(73) Assignee: CALLISTO FRANCE, VILLEFRANCHE DE LAURAGAIS (FR)

(21) Appl. No.: 13/824,915

(22) PCT Filed: Sep. 20, 2011
(86) PCT No.: PCT/EP11/66280

§ 371 Date: Jun. 12, 2013

(30) Foreign Application Priority Data
Sep. 20, 2010 (FR) 1057507

(51) Int. Cl. H03F 1/26; H03F 3/189

(52) U.S. Cl. CPC H03F 1/26; H03F 3/189
USPC 330/1 R

(57) ABSTRACT

A radiofrequency amplifier includes a low noise amplifier (25) maintained in a hermetic cryostat structure (11) cooled by a cold head (30) and in which is maintained a low grade vacuum. The low noise amplifier receives signals from an input coupler (23) and transmits the signals through an output coupler (26). The input and output couplers are made, for a structural part, of a material with thermal conductivity equal or less than 50 W/m·K, and, for an electrically conductive part, of plating on at least one of the faces of the structural part, with a material with electrical conductivity more than 10E7 Siemens/m. The cold head includes at least two stages whose cold terminations are at different cryogenic temperatures, a base stage operating at a temperature close to the temperature at which the low noise amplifier must operate and at least one intermediate stage operating at an intermediate temperature.

The present invention relates to the field of ground reception systems of low power radio frequency signals.

More particularly, the invention relates to a high frequency, low noise amplifier adapted for the reception of weak signals transmitted by space vehicles that can be at a great distance from Earth.

Regarding communications in the field of radiofrequencies, it is sometimes necessary to detect and amplify very weak signals.

This situation occurs particularly in cases where the signal transmitter is situated at a great distance or in poor transmission conditions.

For these reasons communication with interplanetary probes, a certain number of which are today over a billion kilometres away in the solar system, proves very difficult due to the fact that the transmitted signals are very much attenuated due to the great distances between the transmitter and Earth and by the imperfections in pointing of the antenna of the transmitter, which is unavoidable taking into account the angular precision corresponding to these distances.

As it is impossible to increase the power of transmission due to the constraints in design of interplanetary probes and otherwise improve performance, the solutions available today concern the improvement of the ground reception sensitivity on Earth.

A first solution to improve this sensitivity is to increase the size of the reception antenna. It is known that by increasing the size and number of reflectors used in the antenna system, increases the antenna gain G at a given frequency and thus the reception chain sensitivity is increased.

However, there are technical and economical limits to this solution. It is in fact technically challenging to point a large diameter antenna, which also has significant mass, with high precision taking into account that the antenna angular beam width at a given frequency becomes more narrow as the antenna diameter increases.

The cost and constraints associated with large dimension antennas with their steering and pointing devices are penalising, even making this solution prohibitive when the transmitter is moving and the antenna has to track the movement of the target, a general case being due to the Earth's rotation when reception takes place over a significant period of time.

An alternative solution, most often combined with the previous solution, consists of reducing as far as possible the electronic noise in the reception chain and in particular the part of the radio frequency reception chain which has most impact on determining the ratio of the signal to noise.

Other than the choice of quality components, noise reduction can be obtained by cooling to low temperatures the physical components of the amplifiers located at the head of the reception chain of the antenna and thus reduce the electronic noise of thermal origin which is defined as the noise temperature T.

For the needs of sensitive receivers, it is usual to cool the amplifier to cryogenic temperatures of a few Kelvin, typically less than 20K.

However, bringing the temperature of a working radiofrequency amplifier to such low values and maintaining these conditions for the total duration of the operation of the amplifier is complex and requires the use of fragile and costly materials that need frequent intervention for maintenance in order to function at the performance required.

At the present time the combination of these two solutions to improve the factor of merit (G/T) of the reception system allows to ensure the telecommunications link with distant probes. However, it is achieved with the penalty of cost and operating constraints due to the complexity of the technologies in use, particular of the maintenance operations, which decreases the system availability.

In order to compensate for the problems with existing systems and to improve the operational availability of radiofrequency amplifiers particularly adapted for receiving low energy signals and for reducing this system maintenance costs, the invention proposed is for the design of a cryogenic low noise amplifier which simplifies the process of getting to cryogenic temperature and maintaining this temperature, compared to known cryogenic amplifiers.

The radiofrequency reception device of the invention includes a low noise amplifier contained in a hermetically sealed chamber called a cryostat the inside of which is maintained at a reduced pressure compared to the exterior atmospheric pressure. The low noise amplifier receives the signals to amplify from an input coupler hermetically crossing the cryostat wall and transmits the amplified signals through an output coupler also hermetically crossing the cryostat wall. The interior of the cryostat is cooled with a cold head that pumps heat from the device.

The radiofrequency amplifier of the invention contains:
The input and output couplers made with a material with thermal conductivity equal or less than 50 W/m·K and having a thin coating of a material with electrical conductivity greater than 10E7 Siemens/m.
The initial interior pressure of the cryostat before any cooling corresponds to a low grade vacuum between atmospheric pressure and 10 Pa.
The hermetically sealed space within the cryostat is filled with a silica based Nano structural thermal insulator in the form of an aerogel.
The cold head includes at least two stages which are at different cryogenic temperatures, one base temperature stage functioning at a temperature close to the temperature at which the low noise amplifier should operate, for example around 15K, and at least one intermediate stage functioning at an intermediate temperature between the base temperature and ambient temperature, for example around 50K. The base temperature stage of the cold head is thermally linked to the low noise amplifier in order to extract the heat of this low noise amplifier and to obtain the lowest possible temperature. The at least one intermediate cold stage is thermally linked to support structures or to the internal elements inside the cryostat in order to pump the diffused heat inside the structure.

With this arrangement of components that compose the radiofrequency amplifier it is possible to limit thermal losses, to operate the low noise amplifier and the whole amplification chain at a low enough cryogenic temperature in order to reduce the thermal noise of the amplification chain. This can be achieved using a primary or low grade vacuum at initial temperature in the cryostat, unlike a conventional cryogenic amplifier which requires a high grade vacuum.

Depending on the frequency of the signals to be amplified and the required performance for the amplifier, the input and or output couplers can be of waveguide type or of coaxial cable type or using transitions between these types of transmission line inside the cryostat, but in any case, the need to avoid thermal losses by conduction, it is retained as follows:
That a waveguide has a waveguide window in order to cross the cryostat wall in a sealed manner, and the structure of the waveguide walls are made of a material with thermal conductivity equal or less than 50 W/m·K and with an internal surface which is covered with a plating material of electrical conductivity greater than 10E7 Siemens/m. The plating layer is as thin as possible and can be less than a micrometre given the frequencies concerned.
That a coaxial cable has a coaxial connector in order to cross the cryostat wall in a sealed manner, and has a central conductor made with a material with thermal conductivity equal or less than 50 W/m·K and with the external surface of the central conductor covered with a plating material having an electrical conductivity greater than 10E7 Siemens/m and includes an external shield made with a metallic material with thermal conductivity equal or less than 50 W/m·K.

To obtain the highest possible thermal resistance the material with thermal conductivity equal or less than 50 W/m·K, is selected from metallic materials belonging to the stainless steel or iron-nickel alloy families containing around 36% Invar® type nickel, or preferably a ceramic material or a composite material with fibres maintained in a hardened resin to achieve higher thermal resistance but also with higher fabrication costs.

To obtain the best electrical performances, but also to benefit from the properties of these metals to be deposited in thin layers of a few micrometres, the material with electrically conductive greater than 10E7 Siemens/m is chosen from the metal or alloy metal families with silver Ag, gold Au or copper Cu.

In order to allow the cold head to be quickly installed and removed from the cryostat without risking damage to the components inside and without risking deteriorating the sealing joints of the cryostat structure, the cold head is attached to the cryostat structure from the outside by means of a sealed socket.

The objective is enhanced by the design of the socket which includes an internal tube which forms a sheath, that traverses the cryostat structure through an opening, in which the intermediate and final stages of cold head are hold.

In order to limit the interface of the cold head with parts inside the cryostat with only a little risk of being damaged by successive installation and de-installation of the cold head, the internal socket includes thermal links. These thermal links are arranged to obtain a thermal continuity with the support structures or the amplifiers internal elements. These thermal links are each in thermal continuity, that is to say with sufficient physical contact surface and contact pressure or with thermal contraction sufficient enough to ensure the necessary close contact for a low thermal resistance, permitting the flux of heat needed to be extracted to the termination of the cold head, in order to ensure thermal continuity between the cold stages of the cold head and the internal elements of the cryostat that need to be cooled.

To avoid excessive thermal losses through the socket, the internal socket includes communication passages between the interior volume of the sheath formed by the internal tube and the cryostats internal volumes. The passages ensure that the primary vacuum is equalised in the internal volume of the socket but with dimensions small enough to prevent the thermal insulating material in the form of an aerogel which is filling the internal space of the structure from penetrating into the interior space of the socket through these passages.

The performance of the amplification chains are further improved as is necessary by integrating additional components in the cryostat which are to be maintained at cryogenic temperature. These components are for example filters acting on the signals bandwidth, isolators acting on the reflection of the signal, signal couplers.

To reduce the time of intervention when de-installing the cold head it is necessary to wait for the internal temperature of the cryostat to return to a temperature close to ambient temperature, a heating system is provided inside the cryostat of the radiofrequency amplifier.

The description of the invention is made in reference to the figures that illustrate schematically and in a non-limiting way:

FIG. 1: a general perspective view of the amplifier of the invention

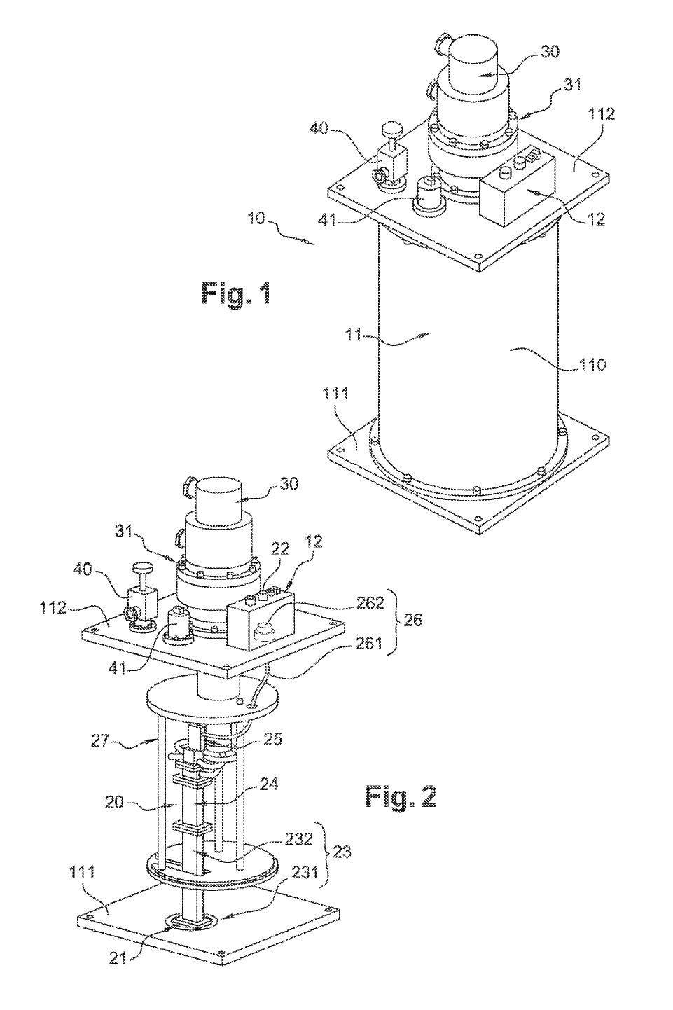

FIG. 2: a perspective view of the amplifier in FIG. 1 without the lateral envelope of the cryostat

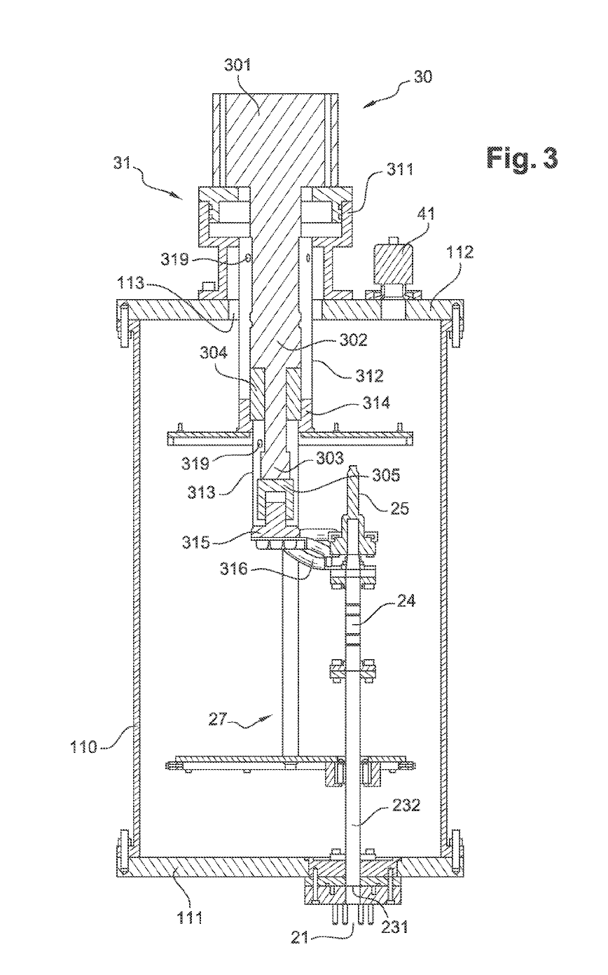

FIG. 3: a cut of the amplifier in the radial plane going through the input waveguide axis

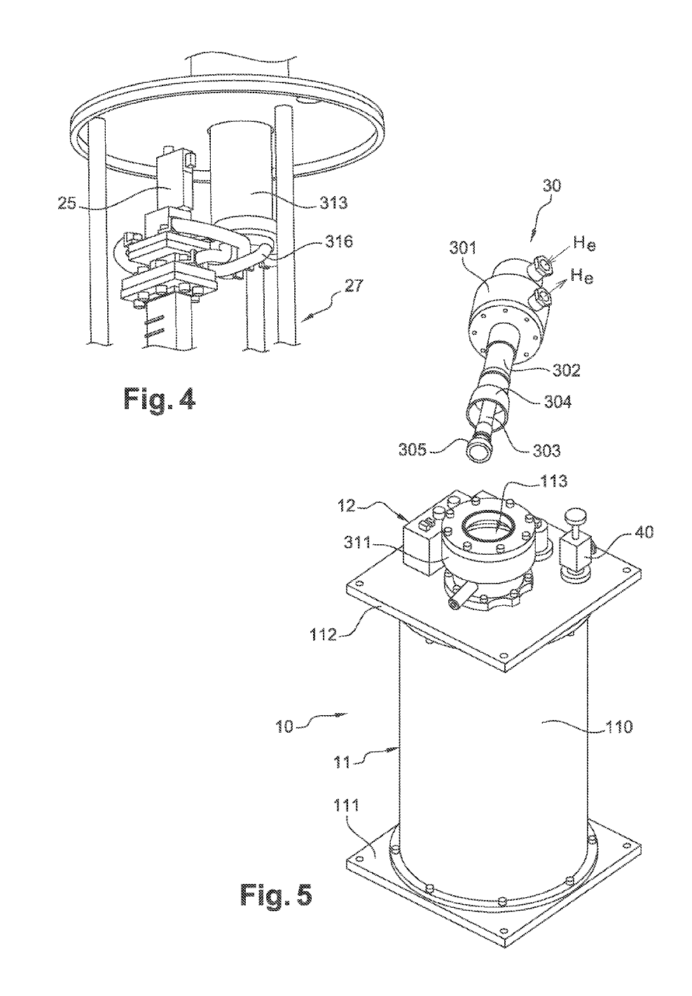

FIG. 4: an enlarged partial perspective view showing the thermal coupling of the low noise amplifiers with the cold head

FIG. 5: a perspective view of the amplifier and the cold head extracted from the amplifier.

As represented in FIG. 1 a cryogenic amplifier (10) following the invention comprises an envelope (11) enclosing, in an internal volume of this envelope, a set of radiofrequency components destined to amplify the signal received by an antenna, which is not represented.

The amplifier considered is destined to amplify high frequency signals, from several hundred megahertz to several hundred gigahertz.

The envelope (11) is mainly constituted of a cylinder shaped lateral envelope (110) and of two base plates, an upper plate (111) and a lower plate (112).

The envelope (11) is designed to be a sealed unit and rigid enough in order to resist to the pressure exerted from the space exterior of the envelope towards the interior of the envelope of around 10E5 Pa, that is to say substantially atmospheric pressure.

In order to meet the sensitivity and signal to noise ratio requirements for the reception of very low power signals transmitted from by far away such as distant interplanetary probes several hundreds of millions of kilometres distance, the amplifier is cooled to cryogenic temperatures, for example under twenty Kelvin, to decrease the noise of thermal origin of the amplifiers electronic components.

Cooling at very low temperatures is necessary for the considered applications given the limitations of the transmission amplifiers installed on interplanetary probes, generally several tens of Watts, and the separating distance during the voyages. These factors make the energy of received signals, from which it is hoped to recover usable information, as low as 10E-15 Watt or even less.

Shown in FIG. 2 is the cryogenic amplifier (10) assembled and represented without the lateral envelope (110), the cryogenic amplifier (10) includes a radiofrequency amplification chain (20), this amplification chain contains an input (21) from the amplifier towards an output (22) from the amplifier:
An input coupler (23), includes in the illustrated case:
A waveguide window (231)
A waveguide (232)
A radiofrequency filter (24)
A low noise amplifier (25)
An output coupler (26), includes in the illustrated case:
A coaxial cable (261)
A sealed coaxial connector (262)

The cryogenic amplifier (10) also includes a cold head (30) crossing the lower base plate (112) and mounted in order to ensure the sealing of the interior volume of the envelope (11).

According to the invention, the arrangement of the different components of the radiofrequency amplification chain (20) in the envelope (11) as well as the structure of this envelope are designed to minimise thermal losses, that is to say minimise the heat flux from the outside to the inside of the envelope (11), and to help maintain the expected cryogenic temperature at twenty Kelvin at the level of the low noise amplifiers (25) but without penalising the operational availability of the amplifier by all necessary maintenance activities.

The envelope (11) is a sealed and insulating structure in thermal terms that forms a cryostat, or Dewar, in which is enclosed the amplification chain (20) whose low noise amplifier (25) is maintained at cryogenic temperature under 20 Kelvin.

To ensure the sealing of the envelope (11), conventional means are implemented between the main elements of this envelope, that is to say the lateral envelope (110) and the upper and lower base plates that are assembled with the interposition of sealing joints at their interfaces.

The sealing of the envelope (11) is also ensured at the level of the input (21) and output (22) of the amplifier (10).

For the amplifier input (21), sealing is ensured by a waveguide window (231) at the level of crossing the lower base plate (111) by the waveguide (232) of the input coupler (23).

The waveguide window (231) is formed at an opening of the lower base plate (111) closed by a thin sheet of dielectric material, transparent to radio waves in the region of the received frequencies. This sheet is held in a sealed manner relative to the base plate between two flanges. Sealing is ensured by a “O” ring on the one hand between the flanges and the thin sheet, and on the other hand by another “O” ring between the waveguide window (231) thus formed, and the upper base plate (111).

For the output of the amplifier (22), sealing is ensured by a hermetic coaxial connector (262) qualified for vacuum, of the output coupler (26), this coaxial connector being mounted in a sealed manner on the lower base plate (112).

To ensure continuous signal passage through the envelope (11) such as the electrical supply of the amplifier and possible amplifier sensors, sealed electrical feed throughs are also foreseen, grouped close to the sealed coaxial connector (262) at the level of an electric connection box (12), fixed to the lower base plate. This box protects the sealed connectors mounted on the lower base plate (112) and also can be used for components of the amplifier that do not need to be cooled to cryogenic temperature.

Sealing of the envelope must also be ensured at the level of the cold head (30) which has to carry and maintain the temperature of the low noise amplifier (25) at 20 Kelvin. This cold head crosses the envelope (11) at the lower base plate through an opening (113) in order to be connected to a helium compressor with pressurised lines.

The way in which the seal is made at the crossing is detailed subsequently with the operation of this cold head.

To achieve the desired cryogenic temperature, it is essential to limit heat transfer between the interior and the exterior of the envelope (11) at ambient temperature otherwise the desired temperature of the low noise amplifier will not be achieved without the need for an oversized cold head.

Heat transfer occurs in different known forms, by conduction, convection and by radiation and the design of the amplifier (10) limits heat transfers under these different forms without needing a high grade vacuum which is generally implemented in equivalent situations.

A high grade vacuum corresponds to pressures less than one microbar (0.1 Pa) and is generally used as an efficient insulation method to restrict heat exchange by convection and conduction.

However, a high grade vacuum is difficult to obtain and maintain, particularly in small structures because of material outgassing in the high grade vacuum space, and the high grade vacuum has to be maintained regularly and generally recreated after return to ambient temperature with complex and expensive turbo molecular pumps.

Moreover, to counteract the heat contributions by radiation it is necessary to insert radiation screens that shield from the effects of infrared radiation.

The arrangement of the envelope (11) as it has just been described requires the implementation of a high grade vacuum inside the envelope.

However, the architecture of the amplifier (10) is such that the heat exchange with the outside are minimised in order to guarantee that the temperature of the low noise amplifier (25) is less than twenty Kelvin without it being necessary to create a high grade vacuum in the envelope (11).

This result is obtained by concentrating the cooling on the support of the low noise amplifier (25) and by isolating this support and the amplifier from heat sources.

In order to limit heat contributions by conduction, the input (23) and output (26) couplers of the amplifier inside the envelope (11), which by necessity constitute a physical continuity between the low noise amplifier (25) and the envelope (11) that isolates from the external environment, and are made with low heat conductive materials.

In the implementation example illustrated in the figures, the input coupler (23) includes the waveguide (232) that receives the radiofrequency signal through the waveguide window (231) to guide the signal towards the low noise amplifier (25) inside the envelope (11), after crossing a filter (24).

The waveguide allows the input coupler to achieve good radio-electric performance, but it must be made from very good electrically conductive materials which in practice are also very good heat conductive materials and therefore incompatible with the amplifier of the invention.

To solve this problem, the waveguide (232) is made of low thermal conductive material, that is to say of thermal conductivity less than 50 W/m·K, at least.

The waveguide (232) is made in a metallic material such as stainless steel or an iron-nickel alloy with a high nickel content Invar® type containing around 36% nickel, whose thermal conductivity is around 13 W/m·K, values compared to those of aluminium or copper, respectively around 200 and 350 W/m·K that means a thermal conductivity of about twenty times lower.

Other, non-metallic materials can also be used, with thermal conductivity very much lower than those quoted above. Thus, it is possible to use materials from the ceramics family or composite materials including fibres, for example carbon filters, kept in a hardened resin insofar as the selected material is able to resist to the cryogenic temperatures of the operating amplifier.

The choice of stainless steel or of a low thermal conductivity Invar® type alloy allows the use of a waveguide material with low electrical conductivity of around 10E6 Siemens/m, and the choice of a ceramic or composite material generally leads to an even lower electrical conductivity, as these later materials are often bad electrical conductors otherwise considered as electrical insulators. These choices are then contrary to obtaining good waveguide performance and to having electrical continuity between the input (21) of the amplifier and the low noise amplifier (25).

To overcome this electrical constraint of the choice of a low thermal conductive material, a thin coat of highly electrically conductive material, above 10E7 Siemens/m, covers the internal surface walls of the waveguide (232) (not shown on the figures).

Such a material is for example silver Ag, with 62 10E6 Siemens/m electrical conductivity, copper Cu with 58 10E6 Siemens/m electrical conductivity, gold Au with 44 10E6 Siemens/m electrical conductivity or an alloy containing these materials whose conductivity is at least 40 to 60 times higher than the material chosen to form the waveguide structure and which is put on the internal surface of the waveguide in the thinnest possible coat depending in the coating technology that is used and depending on the frequency of the signal that is amplified, for example by electrolytic deposition, preferably in a coat thinner than five micrometres or even around a micrometre or less if such thickness is enough to ensure the propagation taking into account the frequency of the signals guided, by the low thermally conductive material.

These principles applied to the waveguide (232) to decrease thermal losses by conduction without losing the radio electric performance of the waveguide are also applied to the filter (24) and to the other elements possibly inserted between the input (21) of the amplifier and the low noise amplifier (25), which allows to greater increase the resulting thermal resistance between this amplifier and the input (21).

In the implementation example illustrated in the figures, the output coupler (22) includes a coaxial cable (261) that transmits the amplified signal inside the envelope (11) from the low noise amplifier (25) to the sealed connector (262).

As in the input coupler (23) of the waveguide (232), the coaxial cable is made to increase its thermal resistance to the maximum without significantly affecting its electric performances with the frequencies in use. Thus, copper, generally used for the conductive parts of the coaxial cables is, in the case of the amplifier of the invention, abandoned in favour of low thermal conductive materials.

In the case of the coaxial cable (261), we use stainless steel which, other than its properties of low thermal conductivity, also has a malleability characteristic enabling the use of drawing methods and the realization of wires with several strands or woven layers.

The coaxial cable (261) conventionally includes a central conductor, a dielectric envelop to the central conductor and a conductive external sheath or covering.

The external sheath is in stainless steel woven with steel wires for example.

The dielectric is a PolyTetraFluoro-Ethylene or PTFE type polymer. The central conductor is also constituted of a stainless steel wire preferably including a single strand plated with good electricaly conduction material such as silver, copper or gold in a thin micron or submicron coat as in the case of the interior wall of the waveguide (231).

Other than the previously explained thermal considerations on the reduction of heat transmission by conduction at the level of input and output couplers, the envelope (11) of the cryostat is filled with a thermally insulating material, which, associated with a low grade vacuum or primary vacuum created at ambient temperature before starting-up the amplifier, isolates the part of the amplification chain (20), particularly the low noise amplifier (25) that needs to be maintained at the lowest possible cryogenic temperature. The insulating material is a solid state low density material. In its preferred form, it is a low density Nano-structured material such as silica SiO2 based Nano-structured material.

Such insulating material is available in the form of a silica aerogel commercially distributed in the form of micro beads or sheets that can be layered. The cavity, for example, is filled with micro beads through an orifice, not shown on the drawings, on a face of the sealed envelope. This orifice is closed with a sealing cap in operational conditions.

Other than the creation of a low vacuum inside the envelope (11) of the cryostat, that is to say a pressure between ambient pressure and 0.1 millibars (10 Pa), which is to say a pressure 100 times higher than high grade vacuum, this pressure will be reduced further naturally under the simple effect of the reduction of temperature by the phenomenon known as cryogenic pumping, proves beneficial by significantly reducing the thermal energy losses but without requiring to recreate vacuum, when the temperature is reduced again after the temperature inside the envelope (11) of the cryostat has been raised to ambient temperature, for example after stopping the amplifier (10).

Such low grade vacuum is easily created with a primary vacuum pump such as a conventional mechanical pump, unlike high grade vacuums that as well as the primary vacuum pump, require the use of a costly and complicated turbo molecular pump, and in addition it would be necessary to operate the pump in the case that the amplifier is returned to a non-cryogenic temperature, even if the cryogenic structure is not opened because a high grade vacuum needs to be maintained in the envelope (11) of the cryostat.

To take advantage of this benefit, the envelope (11) of the cryostat includes a valve (40), provided with an pumping outlet which is linked to the low grade vacuum pump when the vacuum seal has been broken, which is detected by a vacuum indicator (41) fixed to the envelope (11).

To ensure cooling of the components of the amplifier inside the cryostat, the cold head has several cold stages, at least two as in the example illustrated in the figures.

A first stage has a temperature cooled to an intermediate temperature between the target temperature and the ambient temperature, for example 50K, and a second stage with a temperature lower again compared to the first stage to reach the target temperature, for example 15K.

The cold head (30) uses a helium expansion and compression in a closed circuit following a Gifford-Mac Mahon cycle to pump the heat.

The general principle of a multi-stage cold head, functioning according to this principle, is known in the area of liquefying of gases and for superconductive materials used in magnetic coils that need to be cooled to temperatures close to zero K, and that are not detailed here. The patent application published under number GB 2420611 provides an example of a three stage cold head following this principle.

These types of cold heads allow to reach very low target temperatures and use moving mechanical parts incorporated in the head which are a source of wear and potential failure.

It is preferable to install the cold head from the outside of the structure without it being necessary to open the structure (11).

The preferred implementation method of the cold head (30) comprises a first stage (302), or intermediate stage, carrying an intermediate cold termination (304) and a second stage (303), or base stage, carrying a cold termination (305), the said first and second stages having significantly cylindrical shapes forming the internal cold head.

The internal cold head is held in a socket (31), that forms a sheath (312, 313) for the first and second stages, that is attached to the envelope of the cryostat (11), in the illustrated example to the lower base plate (112), in a sealed manner, at the opening of the envelope so that the cold head can be installed and de-installed without it being necessary to disassemble this socket.

Thus, the internal part of the cold head (30) can be taken in or out of the cryostat without opening it and so without risking damage to the structural sealing elements or the components enclosed in the structure, as the internal parts are always confined inside the structure (11) and protected by the socket (31).

The interior volume of the socket (31) is connected with the interior volume of the cryostat with passages (319), small dimensional openings arranged in the wall of the socket, so that the pressure inside the internal tube is reduced like the internal pressure of the cryostat which limits convection and conduction losses between the inside of the socket, where the cold heads cooled stage are located, and the exterior air. Consequently, the cold head (30) is also attached in a sealed manner to the socket (31).

To ensure the thermal transfer of heat, the base stage (303), more precisely the cold termination (315) of said base stage, is linked by thermal links (315, 316) to the low noise amplifier (25) which is the component of the amplifier which needs to be brought down to the lowest temperature. The thermal links are straps made with inert, good heat conductive materials like copper for example.

Moreover, thermal transfer of heat is also ensured at the intermediate stage (302), more precisely by an intermediate cold termination (314) of said intermediate stage, directly or indirectly connected by thermal links (314) to internal elements such as the amplifiers secondary components: waveguide (232), filter (24), coaxial cable (261) . . . that do not require being cooled to temperatures as low as the low noise amplifier, and such as the internal structures (27) of the cryostat use to support the different components which allows that the heating pumping is distributed inside the cryostat.

To allow heat transfer from the cold terminations of the cold head while also allowing the cold head (30) to be de-installed and extracted from the socket (31) without opening the cryostats structure, each terminal (305) and intermediate (304) cold terminal is, when the cold head is installed and the amplifiers functional temperature is established, in close contact with a thermal link (314), respectively 315, integrated within the socket (31), and in direct or indirect thermal continuity with the internal elements amplifier that needs to be cooled.

The close contact here takes into account that the thermal resistance must be as low as possible allowing sufficient conductive heat flux for the heat to be extracted, that is to say with sufficient physical contact surface area and sufficient enough contact pressure, that can be ensured by thermal contraction, to ensure necessary close contact, without however the cold terminals being fixed to the corresponding thermal links.

Thus, when the temperature of the amplifier is brought to ambient temperature, the cold head can be extracted from the socket.

Such an example of the assembly of a cryogenic head in a cryostat through a socket is described in detail in the U.S. Pat. No. 5,235,818 patent or the U.S. Pat. No. 5,934,082 patent.

When the amplifier (10) is functional, all of the components which make up the low noise amplifier (25) and the input (23) and output (26) couplers are attached inside the sealed structure of the cryostat (11), which is filled with a thermal insulator such as an aerogel and inside which a low grade vacuum is created beforehand, and the cold head functions to deliver a temperature around 50K on the intermediate cold termination (304) of the intermediate stage (302), and a temperature around 15K on the final cold termination (305) of the terminal stage (303).

In the scheme established by the operation of the amplifier (10), the intermediate stage of the cold head ensures, with the participation of support structures (27) that are thermally linked to the intermediate stage (302) cold termination (304) by the intermediate thermal link (314), a general transfer of heat which is generated in the cryostat by operating the amplifier or that penetrates from the outside to the inside of the cryostat by residual conduction and convection because of insulation imperfections linked to the absence of high vacuum, and in spite of the aerogel filling as well as by the thermal influence of the walls of the cryostat and of the low noise amplifier (25).

In the structure of the cryostat thus cooled to a relatively low intermediate temperature, but insufficient to obtain the targeted thermal noise reduction, the low noise amplifier (25) is cooled and maintained at the desired temperature for this amplifier by thermal pumping of the base stage of the cold head (303) to which it is linked by the thermal links (315 and 316).

Because of the high thermal resistance of the input (23) and output (26) couplers obtained by the adapted structure of these couplers in conditions that preserve the transmission quality for signals needing to be, or having been, amplified, the temperature of the low noise amplifier (25) is reduced nearly to the temperature that can be reached by the base stage of the cold head (30).

When the temperature of the amplifier (10) is raised to ambient temperature: around 290K, particularly following an intentional or unintentional interruption of the operation of the cold head, it is generally possible, as long as the cryostat has not been opened to the air, to put the amplifier back into service without recreating a low grade vacuum inside the cryostat when the cold head is functional again.

Indeed, the low grade vacuum is not broken by a simple return to ambient temperature, whereas a high grade vacuum is destroyed during such a return to ambient temperature, particularly by the material outgassing inside the cryostat.

If a repair, a replacement or a maintenance operation has to be done on a cold head (30), which requires de-installing the cold head, the low grade vacuum is necessarily destroyed but the cryostat (11) is not opened and the cold head is extracted from the socket (31) by de-installing said cold head through the external part (311) of the socket without forcing the internal parts.

Because of the internal parts of the socket (312, 313) the elements inside the cryostat are mechanically protected and cannot be damaged by this de-installation or by the re-installation of the cold head and the aerogel that fills the structure does not need to be emptied.

When the cold head, or a new cold head, is re-installed and attached in a sealed manner to the socket, the cryostat is sealed again and vacuum can be created by linking a mechanical low grade vacuum pump to the valve (40), the indicator (41) permanently fixed to the structure (11) gives information on the value of the pressure in said structure when the amplifier operates, if necessary.

When this low grade vacuum is sealed, the cold head can be put back into operation to reduce the temperature inside the cryostat as well as reduce the pressure by the cryo-pumping phenomenon and finally that of the low noise amplifier (25).

The amplifier of the invention, an example of implementation of which has just been described in detail, can contain diverse variants which could be envisaged by a skilled person working in the domain given the explanations provided.

Concerning the input and output couplers amplifiers, the implementation details of the waveguide coupler described in the case of the input coupler, can be perfectly well used to create a waveguide output instead of the described coaxial cable.

The input coupler can be realized with a coaxial cable with a structure similar to that of the coaxial cable coupler described in the case of an output coupler.

In practice, the choice of either waveguide couplers or a coaxial cable will be made depending on the performance expected of the amplifier and on cost criteria that depend on the frequencies of the signals needing to be amplified.

Particularly in signal frequencies under around 3 GHz, the insertion losses of the coaxial cable can be low enough to be tolerated.

Concerning the cold head, it is understood that it can include two or more intermediate stages but in practice the thermal performance obtained with the amplifier, with the structure characteristics which have just been described, show that a two stage cold head is more often sufficient for the operation of the amplifier at a temperature close to 15K, and the complexity of a cold head including more than two stages is justified only in the case of an amplifier which needs to be operated below 10 k or with such power that it would be necessary to pump more heat from the low noise amplifier.

To ensure complimentary functions of the amplifiers, or to reach particular performance, other components can be arranged inside the cryostat, such as:
Radiofrequency components to improve rejection of signals outside the bandwidth by bandpass or lowpass filters operating at cryogenic temperatures
An isolator functioning at cryogenic temperature to improve the input reflection at the input of the cryostat, particularly because low noise amplifiers often have mediocre performances at the level of input reflection coefficients, and if needed a cryogenic isolator at the amplifiers output to correct for a high reflection coefficient.
A high-frequency coupler to inject a test signal into the cryostat

These different components are, from an operational point of view, of the same nature as the components already described in the detailed description and they must be treated in a similar way in their structures as well as in their assembly and thermal links inside the amplifiers structure (11).

Other components can be associated with the amplifier for proximity and integration reasons without necessarily being placed in the cold environment inside the structure (11) like for example the low noise post-amplification box, to achieve an overall gain of amplification required for the amplifier (10), the signal having been pre-amplified by the low noise amplifier cooled to cryogenic temperature, thus being less sensitive to thermal noise.

To take complete advantage of the amplifier following the invention concerning preventive or corrective maintenance, a re-heating system, for example using electrical resistances, is distributed inside the cryostat (11).

When the amplifier is stopped for an intervention, after the cold head is switched off, the re-heating system is switched on to bring the internal temperature of the cryostat back to a value close to ambient temperature.

Re-heating is necessary on the one hand to allow de-installation of the cold head when the cold clamp rings are at a high enough temperature and also to avoid water condensation forming inside the structure when the low grade vacuum is broken.

In practice, the obtained thermal performances of the amplifier of the invention are such that the use of the re-heating system allows the total time for which the amplifier is non-operational in order to replace the cold head to be reduced from two days to seven hours.

The amplifier of the invention proves to be particularly advantageous on an operational level having a much lower requirement concerning vacuum quality inside the cryostat and because of the optimisation of thermal flux in terms of installed thermal power and by reducing by about seven times the duration of non-operation for essential cold head replacement, compared to conventional technologies.

1. Radiofrequency amplifier (10) for low power radiofrequency signal reception device including a low noise amplifier (25) maintained in a hermetically sealed space delimited by an envelope (11) of a cryostat in which space a reduced interior pressure is maintained compared to the external atmospheric pressure, said low noise amplifier receiving signals to be amplified from an input coupler (23) crossing the envelope (11) in a sealed manner, and transmitting the amplified signal through an output coupler (26) crossing the envelope (11) in a sealed manner, said space being cooled by a heat pumping cold head (30) inside the structure characterised in that in the radiofrequency amplifier (10):
The input (23) and output (26) couplers are made, for a structural part, from a material with thermal conductivity equal or less than to 50 W/m·K, and for an electrically conductive part by a plating on said structural part made of a material with electrically conductivity higher than 10E7 Siemens/m.
The internal pressure in the envelope (11) of the cryostat, before its temperature is reduced, corresponds to a low grade or primary vacuum pressure of between atmospheric pressure and 10 Pa.
The hermetic space delimited by the envelope (11) is filled with a silicon based nano-structured thermal insulation in the form of an aerogel.
The cold head (30) includes at least two stages (302, 303) whose cold terminations (304, 305) are at different cryogenic temperatures, a base stage (303) operating at a temperature close to the temperature at which the low noise amplifier (25) must operate and at least one intermediate stage (302) operating at a temperature between that of the base stage and ambient temperature, a cold termination (305) of the base stage (303) being thermally linked (315, 316) to the low noise amplifier (25) in order to implement heat pumping of said low noise amplifier and an intermediate cold termination (304) of the at least one intermediate stage (302) being thermally linked (314) to support structures (27) or to internal elements of the amplifiers (10) in order to achieve distributed heat pumping inside the envelope (11).

2. Radiofrequency amplifier as in claim 1, in which the input coupler (23), and or the output coupler, includes a waveguide (232) crossing the envelope (11) of the cryostat in a sealed manner at the level of waveguide windows, said waveguide including structural walls made with a material with thermal conductive equal or less than 50 W/m·K, and with the waveguide internal surface covered with plating material with an electrically conductivity of more than 10E7 Siemens/m.

3. Radiofrequency amplifier as in claim 1, in which the output coupler (26), and or the input coupler, includes a coaxial cable (261) crossing a wall of the envelope (11) of the cryostat in a sealed manner at the level of a coaxial connector (262), said coaxial cable including a central conductor made with a material with thermal conductive equal or less than 50 W/m·K, and with the external surface covered with plating material with an electrically conductivity more than 10E7 Siemens/m, and the said coaxial cable including a shield made from a metallic material with a thermal conductivity equal or less than 50 W/m·K.

4. Radiofrequency amplifier as in claim 2, in which the material with thermal conductivity equal or less than 50 W/m·K is a metallic material belonging to the stainless steel or iron-nickel alloy family including around 36% nickel or a ceramic material or a composite material including fibres maintained in a hardened resin.

5. Radiofrequency amplifier as in claim 4, in which the material with electrical conductivity more than 10E7 Siemens/m belongs to the metal or alloy metal family including silver Ag, gold Au or copper Cu.

6. Radiofrequency amplifier as in claim 1, in which the cold head (30) is attached to the envelope (11) of the cryostat from the outside of said cryostat through a sealed, secured socket (31) to the said envelope.

7. Radiofrequency amplifier as in claim 6, in which the socket (31) includes an internal tube (312, 313) forming a sheath crossing the envelope (11) through an opening (113), in which are held the intermediate (302) and base (303) stages, cold terminations (304, 305) of said cold head (30) being directly, or indirectly, in thermal continuity with the amplifiers internal elements (232, 24, 25, 261, 27) through thermal links (314, 315) fixed to the socket (31).

8. Radiofrequency amplifier as in claim 7, in which the thermal continuity between the cold terminations (304, 305) of the cold head (30) and a corresponding thermal link (314, 315) fixed to the socket (31) is ensured by contact or by clamping when the temperature of the amplifier is low and without clamping when the temperature of the amplifier is close to ambient temperature.

9. Radiofrequency amplifier as in claim 8, in which the internal tube (312, 313) includes communication passages (319) between the internal volume of the sheath formed by said tube and the internal volume of the cryostat envelope.

10. Radiofrequency amplifier as in claim 1, in which accessory components of the amplification chains are arranged in the cryostat so that they are maintained at cryogenic temperature, said accessory components belonging to one of the category of filters (24) acting on the bandwidth of the signals, of the isolators acting on the signals reflection, of signal couplers.

11. Radiofrequency amplifier as in claim 1, in which a re-heating system of said radiofrequency amplifier is arranged inside the envelope (11) of the cryostat.

12. Radiofrequency amplifier as in claim 3, in which the material with thermal conductivity equal or less than 50 W/m·K is a metallic material belonging to the stainless steel or iron-nickel alloy family including around 36% nickel or a ceramic material or a composite material including fibres maintained in a hardened resin.

13. Radiofrequency amplifier as in claim 2 in which the cold head (30) is attached to the envelope (11) of the cryostat from the outside of said cryostat through a sealed, secured socket (31) to the said envelope.

14. Radiofrequency amplifier as in claim 2, in which accessory components of the amplification chains are arranged in the cryostat so that they are maintained at cryogenic temperature, said accessory components belonging to one of the category of filters (24) acting on the bandwidth of the signals, of the isolators acting on the signals reflection, of signal couplers.
